(19) United States
(12) Patent Application Publication
(10) Pub. No.: US 2020/0342282 A1
(43) Pub. Date: Oct. 29, 2020

(54) SEMICONDUCTOR DEVICE AND MANUFACTURING METHOD THEREFOR

(71) Applicant: Panasonic Intellectual Property Management Co., Ltd., Osaka (JP)

(72) Inventors: KOJI OBATA, Osaka (JP); HIDEYUKI ARAI, Osaka (JP); JUN'ICHI NAKA, Osaka (JP)

(21) Appl. No.: 16/955,772

(22) PCT Filed: Feb. 4, 2019
(86) PCT No.: PCT/JP2019/003774

§ 371 Date: Jun. 19, 2020

(30) Foreign Application Priority Data
Feb. 13, 2018 (JP) 2018-023042

(51) Int. Cl. G06K 19/077; H01Q 1/22; H01L 29/786

(52) U.S. Cl. CPC G06K 19/07758; H01L 29/786; H01Q 1/22

(57) ABSTRACT

Improving safety against peeling-off of a semiconductor device from an article and omitting an adhesion work of the semiconductor device to the article are made possible. Provided is semiconductor device including one or more components selected from a group including semiconductor chip, thin film transistor, antenna, and wiring. The one or more components are directly fixed on a surface of article. Provided is a manufacturing method of semiconductor device including one or more components selected from a group including semiconductor chip, thin film transistor, antenna, and wiring. The manufacturing method includes at least one of following step P1 and step Q1: step P1 of directly mounting the semiconductor chip on a surface of an article; and step Q1 of directly forming one or more components selected from a group including the thin film transistor, the antenna, and the wiring on the surface of the article by a printing method.

### TECHNICAL FIELD

The present disclosure relates to a semiconductor device (in particular, wireless communication semiconductor device) such as a radio frequency identification (RFID) tag and an integrated circuits (IC) tag, and a manufacturing method therefor.

### BACKGROUND ART

An external reader device is capable of integrally reading information of a plurality of wireless communication semiconductor devices such as RFID tags or IC tags only by holding the external reader device over the wireless communication semiconductor devices even when the wireless communication semiconductor devices are away from the external reader device as long as the wireless communication semiconductor devices exist within a range (e.g., several millimeters to tens of meters) where radio waves from the external reader device arrive. Accordingly, the wireless communication semiconductor device is very useful for distribution management (logistics management), production management, inventory management, location management, history management, and the like in retail industry such as convenience stores and supermarkets, apparel industry, transportation industry, publishing industry (library), and the like.

The wireless communication semiconductor device typically includes an IC chip including a silicon chip and the like and an antenna that are mounted on a circuit board. The IC chip typically includes a wireless circuit unit for processing radio waves received by the antenna; a memory unit for storing a received signal and the like in the wireless circuit unit; a power supply circuit unit for generating drive power; a control circuit unit for making the memory unit store the received signal and the like, and the like (PTLs 1 to 2).

### CITATION LIST

### Patent Literatures

PTL 1: Japanese Patent No. 4761779

PTL 2: Unexamined Japanese Patent Publication No. 2006-24087

PTL 3: Japanese Utility Model Registration No. 3129548

### SUMMARY OF THE INVENTION

However, as illustrated in FIG. 5, the inventors et al. of the present disclosure have found a new problem that conventional semiconductor device (in particular, wireless communication semiconductor device) 500 has a risk of spontaneous or artificial peeling because of being used in a state of being pasted to article S with paste layer 600. Also, pasting of the semiconductor device (in particular, wireless communication semiconductor device) is performed by a human, a robot, or the like, making the adhesion work extremely complicated.

In PTL 3, a technique has been disclosed in which an antenna is formed on a prescription, and a tag body is joined to a surface of the antenna with an paste layer. However, an paste layer is used also in such a technique, making a joint (paste) work of the tag body complicated.

The present disclosure aims to provide a semiconductor device (e.g., a wireless communication semiconductor device) capable of improving safety against peeling-off of the semiconductor device from an article and eliminating (omitting) a paste work of the semiconductor device to the article, and a manufacturing method therefor.

An aspect of the present disclosure is a semiconductor device including a semiconductor chip and an antenna. The semiconductor chip and the antenna are directly fixed on a surface of an article and exposed from the surface of the article by more than or equal to ½ of respective height dimensions in respective thickness directions.

Another aspect of the present disclosure is a semiconductor device including a thin film transistor and an antenna. The thin film transistor and the antenna are directly fixed on a surface of an article.

Another aspect of the present disclosure is a semiconductor device including at least one of a semiconductor chip and a thin film transistor on an underlayer and an antenna on the underlayer. The at least one of the semiconductor chip and the thin film transistor, and the antenna are directly fixed on a surface of the underlayer, and the underlayer is directly fixed on a surface of an article.

Still another aspect of the present disclosure is a manufacturing method of a semiconductor device including one or more components selected from a group including a semiconductor chip, a thin film transistor, an antenna, and a wiring. The manufacturing method includes at least one step among following steps P1 and Q1:

step P1 of directly mounting the semiconductor chip on a surface of an article; and

step Q1 of directly forming the one or more components selected from a group including the thin film transistor, the antenna, and the wiring on the surface of the article by a printing method.

Still another aspect of the present disclosure is a manufacturing method of a semiconductor device including, on an underlayer, one or more components selected from a group including a semiconductor chip, a thin-film transistor, an antenna, and a wiring. The manufacturing method includes following step O and at least one of steps P2 and Q2:

step O of directly forming the underlayer on a surface of an article;

step P2 of directly mounting the semiconductor chip on a surface of the underlayer; and

step Q2 of directly forming the one or more components selected from a group including the thin-film transistor, the antenna, and the wiring on the surface of the underlayer by a printing method.

The semiconductor device (e.g., wireless communication semiconductor device) of the present disclosure makes it possible to improve safety against peeling-off of a semiconductor device from an article and eliminate (omit) an adhesion work of the semiconductor device to the article.

### BRIEF DESCRIPTION OF DRAWINGS

FIG. 1 is a schematic cross-sectional view illustrating an example of a structure of a semiconductor device according to the present disclosure.

FIG. 2A is a schematic sketch illustrating a step of preparing an article in a manufacturing method of the semiconductor device according to the present disclosure.

FIG. 2B is a schematic sketch illustrating a step of manufacturing an underlayer in the manufacturing method of the semiconductor device according to the present disclosure.

FIG. 2C is a schematic sketch illustrating a step of mounting a semiconductor chip in the manufacturing method of the semiconductor device according to the present disclosure.

FIG. 2D is a schematic sketch illustrating a step of manufacturing an antenna and a wiring in the manufacturing method of the semiconductor device according to the present disclosure.

FIG. 2E is a schematic sketch illustrating a step of forming a protection film in the manufacturing method of the semiconductor device according to the present disclosure.

FIG. 2F is a schematic sketch illustrating another example of the structure of the semiconductor device according to the present disclosure.

FIG. 3A is a schematic cross-sectional view illustrating the step of preparing the article in the manufacturing method of the semiconductor device according to the present disclosure.

FIG. 3B is a schematic cross-sectional view illustrating the step of manufacturing the underlayer in the manufacturing method of the semiconductor device according to the present disclosure.

FIG. 3C is a schematic cross-sectional view illustrating the step of mounting the semiconductor chip in the manufacturing method of the semiconductor device according to the present disclosure.

FIG. 3D is a schematic cross-sectional view illustrating the step of forming the antenna and the wiring in the manufacturing method of the semiconductor device according to the present disclosure.

FIG. 3E is a schematic cross-sectional view illustrating the step of forming the protection film in the manufacturing method of the semiconductor device according to the present disclosure.

FIG. 3F is a schematic cross-sectional view illustrating the other example of the structure of the semiconductor device according to the present disclosure.

FIG. 4A is a schematic sketch illustrating a still another example of the structure of the semiconductor device according to the present disclosure.

FIG. 4B is a schematic cross-sectional view illustrating the still other example of the structure of the semiconductor device according to the present disclosure.

FIG. 5 is a schematic cross-sectional view illustrating a structure of a semiconductor device according to a conventional technique.

### DESCRIPTION OF EMBODIMENT

A semiconductor device of the present disclosure may be any device including a semiconductor, and for example, may be a wireless communication semiconductor device such as an RFID tag or an IC tag. In the description, specifically, a wireless communication semiconductor device among semiconductor devices may be referred to as a “wireless communication device”.

Hereinafter, a semiconductor device of the present disclosure will be described in detail with reference to the drawings. In the drawings, components or members indicated by a common reference numeral denote the same components or members except that their shapes are different unless otherwise specified.

### [Semiconductor Device]

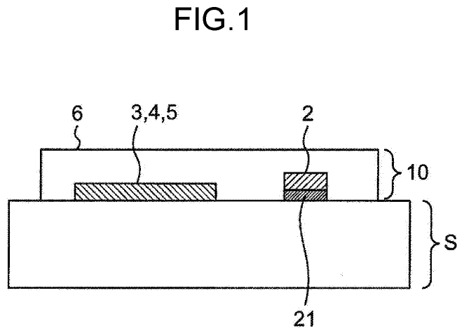

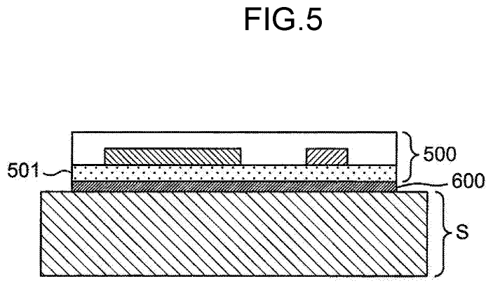

Semiconductor device 10 (e.g., wireless communication device) of the present disclosure is directly fixed on a surface of article S as illustrated in FIG. 1. That the semiconductor device 10 “is directly fixed on the surface of article S” denotes that semiconductor device 10 is fixed to article S with no circuit board (indicated by 501 in FIG. 5) and no paste layer (indicated by 600 in FIG. 5) used in a conventional semiconductor device interposed between with article S. That is, semiconductor device 10 of the present disclosure is a semiconductor device directly fixed on the surface of article S, and is a semiconductor device with no circuit board (circuit board included in a conventional semiconductor device) and no paste layer (adhesive layer for adhering the conventional semiconductor device to an article) interposed between with article S. The semiconductor device of the present disclosure is directly formed or manufactured on a surface of an article without including a circuit board and without using an adhesive layer. Accordingly, the semiconductor device of the present disclosure has achieved space saving (or miniaturization), resulting in further reduction in manufacturing cost. Also, the semiconductor device increases formation freedom of an antenna. The semiconductor device of the present disclosure has a structure inseparable from the article. Note that “fixation” denotes being combined or jointed.

A circuit board (indicated by 501 in FIG. 5) that is not included in the semiconductor device of the present disclosure is a component having a sheet shape or a plate shape to attach, dispose, position or hold components such as a semiconductor chip, a thin film transistor (TFT), an antenna, or a wiring forming a semiconductor device to be distributed and traded as one product or merchandise in a conventional semiconductor device. Accordingly, a circuit board in one semiconductor device is typically one continuous circuit board, and has a dimension capable of holding thereon all components such as the semiconductor chip, the TFT, the antenna, or the wiring forming the one semiconductor device. In a conventional semiconductor device, a polymer substrate made of a polyester resin (e.g., polyethylene terephthalate resin), a polyimide resin, a polyolefin resin (e.g., polyethylene resin, polypropylene resin), a polyphenylene sulfide resin, a polyvinyl formal resin, a polyurethane resin, a polyamide-imide resin, a polyamide resin, or the like; a glass substrate; a paper substrate; or a ceramic substrate is used as a circuit board. A thickness of the circuit board of the conventional semiconductor device is typically more than or equal to 0.1 μm and less than or equal to 2 mm, and preferably more than or equal to 0.1 mm and less than or equal to 2 mm.

The adhesive layer not used in semiconductor device 10 of the present disclosure (indicated by 600 in FIG. 5) is a layer formed of adhesive used for adhering a conventional semiconductor device to an article.

The article to which the semiconductor device of the present disclosure is fixed may be any product, or may be an intermediate obtained in a manufacturing process of such a product. Since the semiconductor device of the present disclosure is fixed to an article or its intermediate, the fixation can be performed in a series of product manufacturing process, and the semiconductor device of the present disclosure becomes to have a structure inseparable from the article. This improves safety against peeling-off of the semiconductor device from the article, making it possible to eliminate (omit) an adhesion work of the semiconductor device to the article. Examples of the article include any product and an intermediate thereof to which a conventional semiconductor device (e.g., wireless communication device) is adhered. Specifically, examples of the product to which the semiconductor device (e.g., wireless communication device) of the present disclosure is adhered include a marketable finished product such as a tool, medical equipment, a luxury brand good, and a container. Directly fixing the semiconductor device of the present disclosure on a surface of a marketable finished product makes it possible to apply a function of semiconductor device after the product is completed. The semiconductor device (e.g., wireless communication device) of the present disclosure can also be applied to a tag of a lending article such as a bicycle, a retail merchandise package, or an apparel product, for example.

An article to which the semiconductor device of the present disclosure is fixed may have any shape. A surface of article S to which the semiconductor device of the present disclosure is fixed specifically has a planner shape in FIG. 1 and the like, but the surface may have a three-dimensional shape. When the semiconductor device of the present disclosure is a wireless communication device, and the surface of article S to which the semiconductor device is fixed has the three-dimensional shape, an antenna can be made to have a three-dimensional shape, making it possible to reduce effect on antenna directivity to increase antenna reception sensitivity in any direction as a whole. Although an antenna having a planner shape is typically difficult in reading (receiving) radio waves from a lateral direction (an in-plane direction of the plane), the antenna having the three-dimensional shape can relatively readily read (receive) radio waves from any direction. The three-dimensional shape denotes a shape of a surface of a three-dimensional structure, and may be a non-planer shape such as a curved surface shape.

As illustrated in FIG. 1, semiconductor device 10 of the present disclosure includes one or more components selected from a group including semiconductor chip 2, thin film transistor (TFT) 3, antenna 4, wiring 5, and the like (which may be hereinafter referred to as a semiconductor chip and the like). In FIG. 1, “3, 4, 5” denotes that any of TFT 3, antenna 4, and wiring 5 may be provided. Semiconductor device 10 of the present disclosure typically further includes protection film 6 as illustrated in FIG. 1. FIG. 1 is a schematic cross-sectional view illustrating a structural example of the semiconductor device of the present disclosure.

In the present disclosure, all components included in semiconductor device 10 are directly fixed on a surface of article S. As described above in detail, all components are fixed to article S with no circuit board and no paste layer interposed between with article S. Fixation may be achieved by bonding between a print, a coating, or a film and the surface of article S due to intermolecular force by directly forming a component on a surface of article S by a printing method, a coating method, a vacuum deposition method, or the like. As another method, fixation may be achieved also by bonding between a component and the surface due to adhesive strength with an adhesive or the like by adhering the component to the surface of article S with the adhesive or the like. It is preferable that fixation of a component other than semiconductor chip 2 (e.g., TFT 3, antenna 4, and wiring 5) is achieved by bonding by intermolecular force or the like and fixation of semiconductor chip 2 is achieved by bonding by adhesive strength or the like from a viewpoint of further improving safety against peeling-off of the semiconductor device from the article.

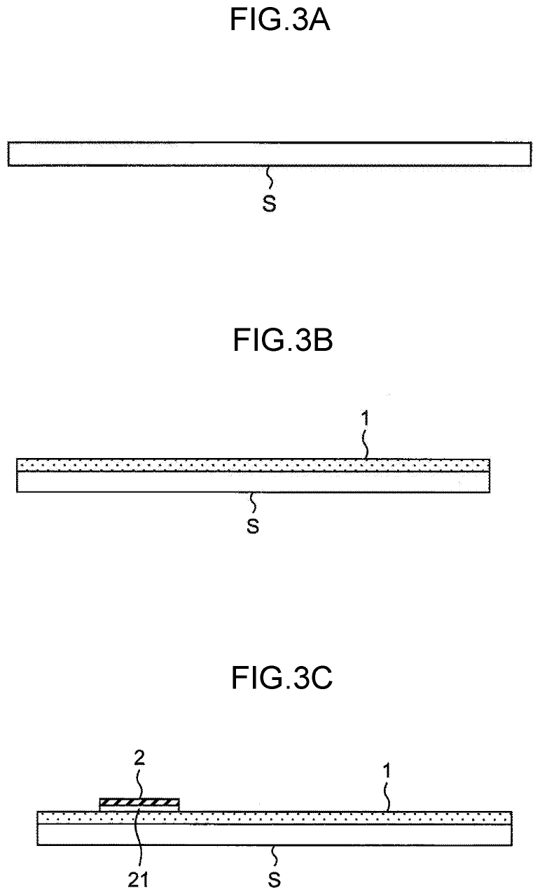

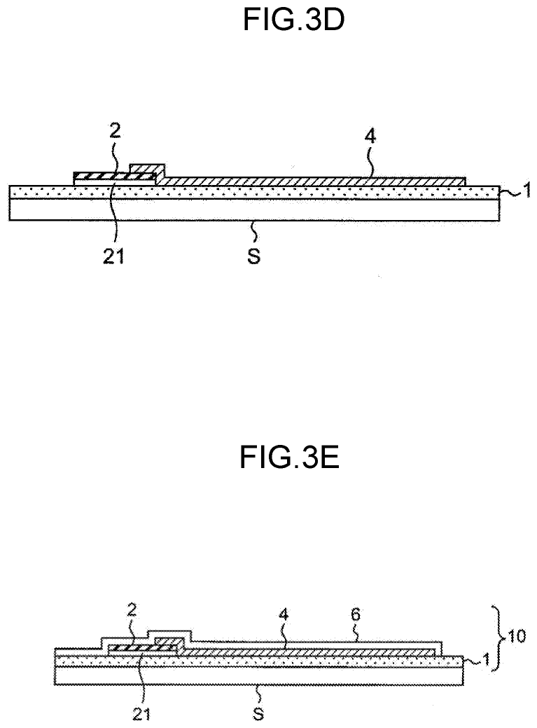

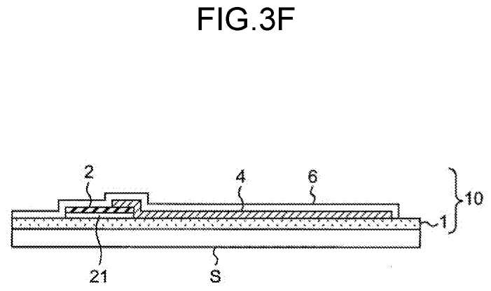

Specifically, for example, when semiconductor device 10 includes semiconductor chip 2, semiconductor chip 2 is directly mounted on the surface of article S. As a result, although adhesive layer 21 (see FIG. 3C) for mount is interposed between with article S, semiconductor chip 2 is combined or joined to the surface of article S with no circuit board and no paste layer interposed. “Mount” denotes that the semiconductor chip preliminarily manufactured or obtained is combined with an adhesive. “Adhesive layer” denotes a layer formed of an adhesive conventionally used for mounting the semiconductor chip. A rubber-based adhesive, an epoxy-based resin, a hot melt adhesive, or the like is typically used as the adhesive.

In the semiconductor device of the present disclosure, a semiconductor chip is directly mounted on a surface of the article. To supplement further, “mount” denotes that the semiconductor chip is combined to a surface of the article in an aspect of being exposed by more than or equal to 1/2 of a height dimension of the semiconductor chip from the surface of the article. For example, an aspect (burial) in which the semiconductor chip is buried in the article is not included.

Also, for example, when semiconductor device 10 includes TFT 3, this TFT 3 is directly formed on the surface of article S, so that TFT 3 is directly combined or joined to the surface of article S with no circuit board and no paste layer interposed between with article S.

Also, for example, when semiconductor device 10 includes antenna 4, this antenna 4 is directly formed on the surface of article S, so that antenna 4 is directly combined or joined to the surface of article S with no circuit board and no paste layer interposed between with article S.

Also, for example, when semiconductor device 10 includes wiring 5, this wiring 5 is directly formed on the surface of article S, so that wiring 5 is directly combined or joined to the surface of article S with no circuit board and no paste layer interposed between with article S.

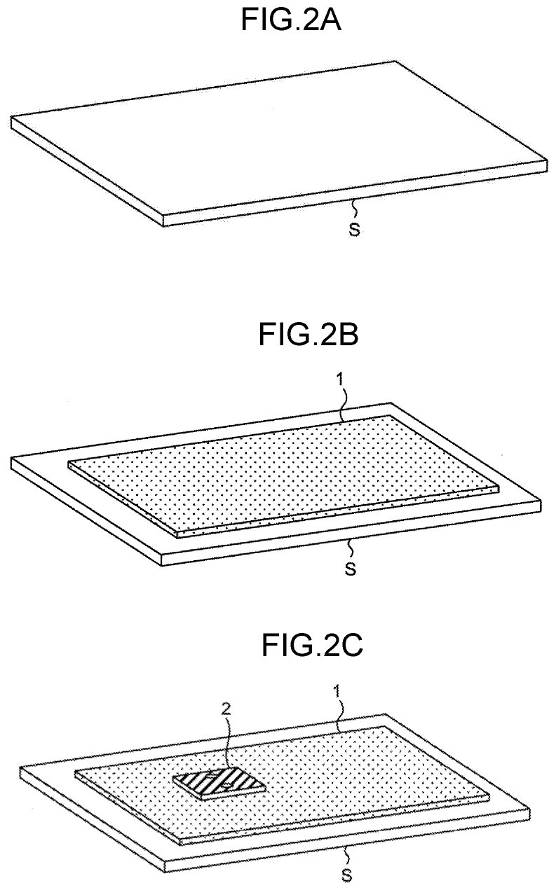

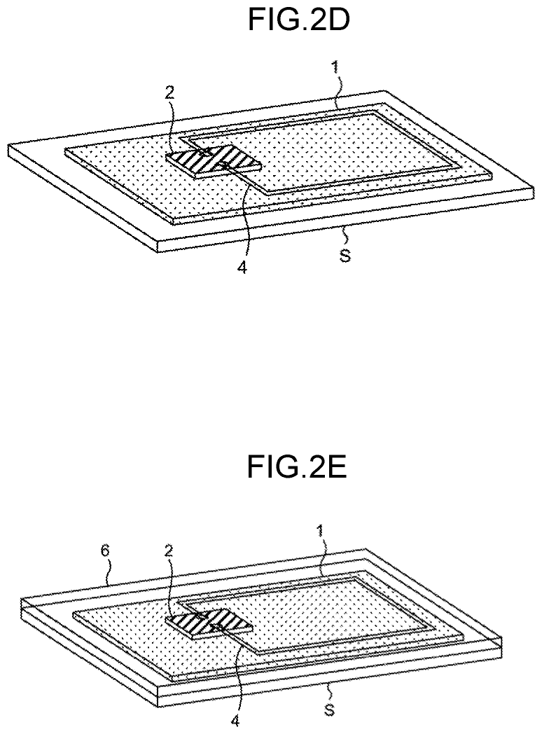

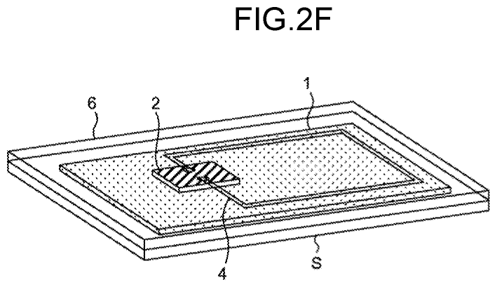

Semiconductor device 10 of the present disclosure may have semiconductor chip 2 or the like on underlayer 1 as illustrated in FIG. 2F and FIG. 3F. For example, semiconductor device 10 of the present disclosure may include underlayer 1 as one component on a side of article S on which semiconductor chip 2 and the like forming the semiconductor device are provided. Specifically, when the surface of article S is made of a metal, semiconductor device 10 of the present disclosure preferably includes semiconductor chip 2 and the like on underlayer 1. Semiconductor device 10 of the present disclosure typically also includes protection film 6 as illustrated in FIG. 1. FIG. 2F and FIG. 3F are respectively a schematic sketch and a schematic cross-sectional view illustrating another example of the structure of the semiconductor device of the present disclosure.

When semiconductor device 10 includes underlayer 1 between with article S as illustrated in FIG. 2E and FIG. 3E, this underlayer 1 is directly formed on the surface of article S, so that underlayer 1 is directly fixed (that is, bounded or joined) to the surface of article S with no circuit board and no paste layer interposed between with article S. In this case, each of semiconductor chip 2 and the like included in the semiconductor device achieves the above-mentioned “fixation” to the surface of underlayer 1 instead of the surface of article S.

In the exemplary embodiment in which semiconductor device 10 includes underlayer 1 between with article S as illustrated in FIG. 2E and FIG. 3E, specifically, for example, when semiconductor device 10 includes semiconductor chip 2, the semiconductor chip 2 is directly mounted on a surface of underlayer 1, so that semiconductor chip 2 is combined or joined to the surface of underlayer 1 with no circuit board and no paste layer interposed between with underlayer 1 while adhesive layer 21 for mount is interposed between with the underlayer.

In the semiconductor device of the present disclosure, it is preferable that the semiconductor chip is not exposed by more than ½ of a height dimension (thickness dimension) of the semiconductor chip from the surface of the underlayer in a thickness direction of the semiconductor chip (that is, is sunk by more than or equal to ½). In contrast, it is preferable that the antenna is exposed by more than or equal to ½ (50 to 100%) of a height dimension (thickness dimension) of the antenna from the surface of the underlayer in a thickness direction of the antenna. Making a step between the semiconductor chip and the underlayer small makes it possible to readily print the antenna without causing disconnection.

Also, underlayer 1 may also function as an adhesive to make semiconductor chip 2 be directly fixed on the surface of article S with noadhesive 21 interposed. Note that, in this case, it can be certified that an area of underlayer 1 on a side of semiconductor chip 2 is the adhesive, and an area of underlayer 1 on a side opposite to semiconductor chip 2 is the underlayer.

Also, for example, when semiconductor device 10 includes TFT 3 (omitted in FIG. 2E and FIG. 3E), this TFT 3 is directly formed on the surface of underlayer 1, so that TFT 3 is directly combined and/or joined to the surface of underlayer 1 with no circuit board and no paste layer interposed between with underlayer 1.

Also, for example, when semiconductor device 10 includes antenna 4, this antenna 4 is directly formed on the surface of underlayer 1, so that antenna 4 is directly combined or joined to the surface of underlayer 1 with no circuit board and no paste layer interposed between with the underlayer.

Also, for example, when semiconductor device 10 includes wiring 5 (omitted in FIG. 2E and FIG. 3E), this wiring 5 is directly formed on the surface of underlayer 1, so that wiring 5 is directly combined or joined to the surface of underlayer 1 with no circuit board and no paste layer interposed between with underlayer 1.

Underlayer 1 that may be included in semiconductor device 10 of the present disclosure is a layer to optimize a surface state of the article. This enables semiconductor device 10 to be fixed to any article. The optimization denotes that electrical conduction of the component in semiconductor device 10 to the article is surely avoided, that moisture penetration to semiconductor device 10 from the article is surely avoided, that adhesion of semiconductor chip 2 to the article is made possible, and that formation of at least one of antenna 4 and wiring 5 is made possible. Underlayer 1 is not specifically limited as long as it has so-called electrical insulation property, and for example, may be an organic layer such as a polymer layer, or may be an inorganic layer such as a glass layer or a ceramic layer. Underlayer 1 typically is a polymer layer. Electrical insulation property denotes that, for example, resistivity is more than or equal to 10⁸ Ωm, and preferably 10⁸ Ωm to 10¹⁷ Ωm. A polymer forming the polymer layer may be, for example, at least one kind of resin material selected from a group including a polyester resin (e.g., polyethylene terephthalate resin), a polyimide resin, a polyolefin resin (e.g., polyethylene resin, polypropylene resin), a polyphenylene sulfide resin, a polyvinyl formal resin, a polyurethane resin, a polyamide-imide resin, a polyamide resin, a fluorine resin, and the like. The polymer preferably is the fluorine resin.

A thickness of underlayer 1 is not specifically limited, and it is sufficient that the thickness is determined as appropriate depending on usage (e.g., type of attachment target of wireless communication device) of the semiconductor device of the present disclosure. The thickness of underlayer 1 may be, for example, more than or equal to 0.1 μm, and preferably more than or equal to 10 μm. An upper limit of the thickness of underlayer 1 is not specifically limited, and the thickness typically is less than 100 μm, and preferably less than or equal to 50 μm.

Semiconductor chip 2 is a semiconductor element mounted on article S or underlayer 1, and is an electronic device also called semiconductor integrated circuit. As semiconductor chip 2, a silicon chip, and an inorganic-based semiconductor chip such as a compound semiconductor are mainly used. The semiconductor chip that will be described later is not specifically limited as long as it is a semiconductor device capable of forming a member such as a wireless circuit unit, a memory unit, a power supply circuit unit, or a control circuit unit, and for example, may be a component distributable and available in a minimum unit in the market. One or more semiconductor chips 2 are used for one semiconductor device, and typically one semiconductor chip 2 is used for one semiconductor device.

In the semiconductor device of the present disclosure, the semiconductor chip is preferably exposed by more than or equal to ½ of the height dimension (thickness dimension) of the semiconductor chip from the surface of the article in the thickness direction of the semiconductor chip. The antenna is also preferably exposed by more than or equal to ½ of the height dimension (thickness dimension) of the antenna from the surface of the article in the thickness direction of the antenna. Mounting the semiconductor chip and the antenna on the surface of the article in an exposed state eliminates to preliminarily secure a place where the semiconductor chip and the antenna are disposed and makes it possible to mount them in a free space of the article.

In FIG. 1, semiconductor chip 2 is exposed by more than or equal to ½ (50 to 100%) in its thickness direction (a direction parallel to a direction along a short side of semiconductor chip 2). Likewise, antenna 4 is exposed by more than or equal to ½ in its thickness direction (a direction parallel to a short side of antenna 4).

In the semiconductor device of the present disclosure, the semiconductor chip may be a packaged semiconductor chip, or may be a semiconductor bare chip that is not packaged. However, the semiconductor bare chip has an advantageous for miniaturization and thinning of the semiconductor device.

Semiconductor chip (in particular, silicon chip) 2 is disposed in a face-up manner (state), that is, disposed such that a pad is oriented in an upper direction. Herein, “upper” denotes “upper direction” when the semiconductor chip is mounted on the surface of the article or the surface of the underlayer as a substantially horizontal plane. The mounting is, for example, mounting in which a surface of the semiconductor chip having a maximum area is made to be a bottom surface. Disposing the semiconductor chip in the face-up manner enables to simplify a manufacturing process by integral formation such that the pad of the semiconductor chip and the wiring are connected when the antenna or the TFT and the wiring are formed.

TFT 3 is a switch that passes current to a drain electrode from a source electrode by controlling electric potential of a gate electrode, and is not specifically limited as long as it is a semiconductor thin film device that will be described later capable of forming a member such as a wireless circuit unit, a memory unit, a power supply circuit unit, or a control circuit unit that will be described later. The TFT may be any known TFT, and for example, may be an organic TFT whose channel part (layer) between the source electrode and the drain electrode is made of an organic-based semiconductor material, or may be an inorganic TFT whose channel part (layer) is made of an inorganic-based semiconductor material. Besides a high molecular material (e.g., polythiophene or its derivative) and a low molecular material (e.g., pentacene or solubilized pentacene), the organic TFT may be made of, for example, a nano carbon material (e.g., carbon nanotube, SiGe nanowire, fullerene, modified fullerene) or a composite of inorganic and organic materials (e.g., complex of (C₆H₅C₂H₄NH₃) and SnI₄). The inorganic TFT may be, for example, a silicon-based TFT such as an amorphous-based silicon TFT or a polycrystalline silicon-based TFT.

A structure of TFT (in particular, organic TFT) 3 may be any known structure, and for example, may be so-called a bottom gate-bottom contact type, a top gate-bottom contact type, a bottom gate-top contact type, or a top gate-top contact type. From a viewpoint of further reducing manufacturing cost and further improving manufacture easiness of the TFT, the TFT is preferably a bottom gate-top contact type organic TFT.

TFT 3 is preferably a printed component from a viewpoint of further reducing manufacturing cost and further improving manufacture easiness of the TFT. That TFT 3 is a printed component denotes that TFT 3 is a component manufactured by a printing method described later.

TFT 3 is preferably an organic TFT from a viewpoint of further improving safety against peeling-off of the semiconductor device from the article, further reducing manufacturing cost, and further improving manufacture easiness of the TFT. This is because the organic TFT further improves security performance while making it possible to be readily manufactured with a simpler structure by a printing method (in particular, inkjet printing method) as described later.

One or more TFTs 3 may be used for one semiconductor device (in particular, wireless communication device). When the semiconductor device (in particular, wireless communication device) of the present disclosure includes protection film 6 described later, every TFT 3 is electrically connected to semiconductor chip 2 with wiring 5 formed under protection film 6 (that is, between article S or underlayer 1 and protection film 6).

Antenna 4 is not specifically limited as long as it can receive radio waves from an external reader device and transmit radio waves based on information or data stored in the semiconductor device (in particular, wireless communication device) to the external reader device. A type of antenna 4 is typically determined depending on a frequency of radio waves, and for example, may be a loop antenna, a spiral antenna, a dipole antenna, a patch antenna, or a bent dipole antenna. Specifically, the dipole antenna is preferable when the frequency of radio wave is 860 MHz to 2450 MHz.

A thickness of antenna 4 is not specifically limited, and for example, may be more than or equal to 50 nm, and is typically 10 nm to 100 μm.

A dimension of antenna 4 is not specifically limited. For example, for an antenna that is the bent dipole antenna, a full length of the antenna in a longitudinal direction is typically 10 mm to 200 mm, and preferably 50 mm to 100 mm, and one example thereof is 70 mm, and a full length of the antenna in a width direction perpendicular to the longitudinal direction is typically 5 mm to 50 mm, and preferably 5 mm to 20 mm, and one example thereof is 9.5 mm.

Antenna 4 is preferably a printed component from a viewpoint of further improving safety against peeling-off of the semiconductor device from the article, further reducing manufacturing cost, and further improving manufacture easiness of the antenna. That antenna 4 is a printed component denotes that antenna 4 is a component manufactured by a printing method described later.

Antenna 4 is not specifically limited as long as it is formed of a material having conductivity, and for example, may be formed of a metallic material such as silver (Ag), copper (Cu), nickel (Ni), aluminum (Al), or stainless (SUS).

Wiring 5 is a wiring to electrically connect semiconductor chip 2, TFT 3, and antenna 4 to each other. Specifically, wiring 5 typically further includes a wiring electrically connecting semiconductor chip 2 and antenna 4 to each other (not shown in FIG. 1), or a wiring electrically connecting TFT 3 and antenna 4 to each other (not shown in FIG. 1).

A thickness of wiring 5 is not specifically limited, and for example, may be more than or equal to 50 nm, and is typically 10 nm to 100 μm.

Wiring 5 is preferably a printed component from a viewpoint of further reducing manufacturing cost and further improving manufacture easiness of the wiring. That wiring 5 is a printed article denotes that wiring 5 is a component manufactured by a printing method described later.

Wiring 5 is not specifically limited as long as it is formed of a material having conductivity, and for example, may be formed of a metallic material such as silver (Ag), copper (Cu), nickel (Ni), aluminum (Al), or stainless (SUS).

Protection film 6 is formed to cover at least semiconductor chip 2 and the like on a side of article S or underlayer 1 on which semiconductor chip 2 and the like are formed, and protects and encloses semiconductor chip 2 and the like. In FIG. 1, FIG. 2E, and FIG. 3E, protection film 6 is indicated as a transparent film for describing other members, but protection film 6 is not limited thereto, and may be an opaque film.

A material forming protection film 6 is not specifically limited as long as it can protect semiconductor chip 2 and the like from moisture in air, and examples thereof include an epoxy resin, a polyimide (PI) resin, an acrylic resin, a polyethylene terephthalate (PET) resin, a polyethylene naphthalate (PEN) resin, a polyphenylene sulfide (PPS) resin, a polyphenylene ether (PPE) resin, a fluorine resin, and those composites. The material preferably is the fluorine resin.

A thickness of protection film 6 is not specifically limited, and preferably is within a range of about 0.1 μm to about 5 μm, more preferably is within a range of about 0.5 μm to about 2 μm, and is about 1 μm for example.

Protection film 6 is preferably a printed component from a viewpoint of further reducing manufacturing cost and further improving manufacture easiness of the protection film. That protection film 6 is a printed component denotes that protection film 6 is a component manufactured by a printing method described later.

### [Manufacturing Method of Semiconductor Device]

For example, when semiconductor device 10 of the present disclosure includes one or more components selected from a group including semiconductor chip 2, TFT 3, antenna 4, and wiring 5, this semiconductor device 10 can be manufactured by a method including at least one of following step P1 and step Q1:

step P1 of directly mounting semiconductor chip 2 on the surface of article S; and

step Q1 of directly forming one or more components selected from a group including TFT 3, antenna 4, and wiring 5 on the surface of article S by a printing method.

Step P1 need not be performed when semiconductor device 10 includes no semiconductor chip 2.

Step Q1 need not be performed when semiconductor device 10 includes no TFT 3, no antenna 4, and no wiring 5.

When semiconductor device 10 includes one or more components selected from the group including semiconductor chip 2, TFT 3, antenna 4, and wiring 5, implementation order of step P1 and step Q1 is not specifically limited as long as the semiconductor device of the present disclosure can be manufactured. For example, step Q1 may be performed after step P1, step P1 may be performed during implementation of step Q1 and after that a remaining part of step Q1 may be performed, or step P1 may be performed after step Q1. Specifically, when semiconductor device 10 includes semiconductor chip 2 and TFT 3, in a preferable manufacturing method of the semiconductor device from viewpoint of further improving safety against peeling-off of the semiconductor device from the article, further reducing manufacturing cost, and further improving manufacture easiness, semiconductor chip 2 is mounted in step P1 after forming TFT 3 by a printing method in step Q1, and antenna 4 and wiring 5 are formed by a printing method in step Q1 as desired.

Also, for example, when semiconductor device 10 according to the present disclosure includes one or more components selected from a group including semiconductor chip 2, TFT 3, antenna 4, and wiring 5 on underlayer 1, this semiconductor device 10 can be manufactured by a method including following step O and at least one of steps P2 and Q2:

step O of directly forming underlayer 1 on the surface of article S;

step P2 of directly mounting semiconductor chip 2 on the surface of underlayer 1; and

step Q2 of directly forming one or more components selected from a group including TFT 3, antenna 4, and wiring 5 on underlayer 1 by a printing method.

Step P2 need not be performed when semiconductor device 10 includes no semiconductor chip 2 on underlayer 1.

Step Q2 need not be performed when semiconductor device 10 includes no TFT 3, no antenna 4, and no wiring 5 on underlayer 1.

When semiconductor device 10 includes one or more components selected from a group including semiconductor chip 2, TFT 3, antenna 4, and wiring 5 on underlayer 1, implementation order of step O, step P2, and step Q2 is not specifically limited as long as manufacture of the semiconductor device of the present disclosure is possible. Specifically, step P2 and step Q2 are performed after step O is performed. As to implementation order of Step P2 and step Q2, for example, step Q2 may be performed after step P2, step P2 may be performed during implementation of step Q2 and thereafter a remaining part of step Q2 may be performed, or step P2 may be performed after step Q2. Specifically, when semiconductor device 10 includes semiconductor chip 2 and TFT 3 on underlayer 1, semiconductor device 10 is formed as described below from a viewpoint of further improving safety against peeling-off of the semiconductor device from the article, further reducing manufacturing cost, and further improving manufacturability. That is, step O is performed, and TFT 3 is formed by a printing method in step Q2, and thereafter semiconductor chip 2 is mounted in step P2, and antenna 4 and wiring 5 are formed by a printing method in step Q2 as desired.

Hereinafter, the above-mentioned preferable manufacturing method of the semiconductor device will be described.

The manufacturing method of the semiconductor device includes:

first, step R of directly forming underlayer 1 on the surface on article S as desired;

step S of forming TFT 3 on article S or underlayer 1 by a printing method;

step T of mounting semiconductor chip 2 on article S or underlayer 1; and

step U of forming antenna 4 and wiring 5 on article S or underlayer 1 by a printing method.

The manufacturing method of the semiconductor device typically further includes step V of forming protection film 6 by a printing method on semiconductor chip 2, TFT 3, antenna 4, and wiring 5 mounted or formed on at least one of article S and underlayer 1.

### (Step R)

In step R, article S is prepared as illustrated in FIG. 2A and FIG. 3A, and thereafter underlayer 1 is formed on article S as desired as illustrated in FIG. 2B and FIG. 3B as desired. FIG. 2A and FIG. 3A are respectively a schematic sketch and a schematic cross-sectional view illustrating a preparation step of the article in the manufacturing method of the semiconductor device of the present disclosure. FIG. 2B and FIG. 3B are respectively a schematic sketch and a schematic cross-sectional view illustrating a manufacturing step of the underlayer in the manufacturing method of the semiconductor device of the present disclosure. Although underlayer 1 is formed in FIG. 2B and FIG. 3B, underlayer 1 need not necessarily be formed.

Underlayer 1 can be manufactured by any coating technologies. Such coating technologies include, for example, coating methods such as a spin coating method, a wire bar coating method, a brush coating method, a spray coating method, and a gravure roll coating method; and printing methods such as an inkjet printing method, a screen printing method, a gravure printing method, a gravure offset printing method, a reverse offset printing method, and a flexographic printing method. It is preferable that the underlayer be manufactured by the coating method from a viewpoint of further reducing manufacturing cost and further improving manufacture easiness of the underlayer. As to a coating liquid used for the coating method or an ink used for the printing method for manufacturing the underlayer, a desired underlayer material (polymer) may be dispersed in a solvent or the polymer is dissolved in the solvent. After the underlayer is manufactured by the coating method or the printing method, the solvent is typically dried. In this context, hardening may occur as needed. A drying temperature (hardening temperature) is typically 150° C. to 250° C., preferably 150° C. to 220° C., and one example is 180° C.

### (Step S)

Although TFT 3 is formed by a printing method, it is not necessary that TFT 3 be formed by the printing method, and may be formed by any thin film forming technology. Examples of the printing method include an inkjet printing method, a screen printing method, a gravure printing method, a gravure offset printing method, a reverse offset printing method, and a flexographic printing method. Besides the above-mentioned printing methods, examples of the thin film forming technology include a sputtering method, an evaporation method, an ion plating method, and a vacuum deposition method such as a plasma chemical vapor deposition (CVD) method. TFT 3 is preferably formed by a printing method (in particular, inkjet method) from a viewpoint of further reducing manufacturing cost and further improving manufacture easiness of TFT 3.

Hereinafter, a forming method of TFT 3 by a printing method will be describe in detail. Note that, although a method of forming a bottom gate-top contact type organic TFT will be described as TFT 3, another TFT may be formed by a known method.

TFT 3 can be formed by a method including following steps:

step of forming a gate electrode;

step of forming an insulating layer on the gate electrode;

step of forming a semiconductor layer on the insulating layer; and

step of forming a source electrode and a drain electrode such that the semiconductor layer is disposed between the source electrode and the drain electrode in plan view.

### Step of Forming Gate Electrode

The gate electrode is formed at a predetermined position on circuit board 1. Examples of a material of the gate electrode include a metallic material such as gold (Au), silver (Ag), copper (Cu), nickel (Ni), chromium (Cr), cobalt (Co), magnesium (Mg), calcium (Ca), platinum (Pt), molybdenum (Mo), iron (Fe), or zinc (Zn), and a conductive oxide such as a tin oxide (SnO₂), an indium tin oxide (ITO), a fluorine-containing tin oxide (FTO), a ruthenium oxide (RuO₂), an iridium oxide (IrO₂), and a platinum oxide (PtO₂).

A method of forming the gate electrode is not specifically limited, and a common practice electrode forming method may be employed. The gate electrode is preferably formed by a printing method (in particular, inkjet printing method) from a viewpoint of further reducing manufacturing cost, and further improving manufacture easiness of TFT 3. In the present exemplary embodiment, the gate electrode is formed by depositing a silver film with a silver nano ink by the inkjet printing method. A thickness of the gate electrode is preferably within a range of about 10 nm to about 100 nm, and more preferably within a range of about 15 nm to about 50 nm (e.g., about 30 nm). An ink used for a printing method for forming the gate electrode is an ink (e.g., silver nano ink) including a conductive material such as the above-mentioned metallic material or a conductive oxide. An ink for forming the gate electrode is typically an ink in which a conductive material is dispersed in a solvent. The solvent is typically dried after forming the gate electrode. A drying temperature is typically 100° C. to 200° C., preferably 120° C. to 180° C., and one example is 150° C.

### Step of Forming Insulating Layer

The insulating layer is formed on the gate electrode. The insulating layer can be a resin-based or inorganic insulator-based insulating film. Examples of the resin-based insulating film include a film formed of an epoxy resin, a polyimide (PI) resin, a polyphenylene ether (PPE) resin, a polyphenylene oxide resin (PPO), or a polyvinyl pyrrolidone (PVP) resin. In contrast, examples of the inorganic insulator-based insulating film include a film formed of a metal oxide such as tantalum oxide (Ta₂O₅, etc.), aluminum oxide (Al₂O₃, etc.), silicon oxide (SiO₂, etc.), zeolite oxide (ZrO₂ etc.), titanium oxide (TiO₂, etc.), yttrium oxide (Y₂O₃, etc.), lanthanum oxide (La₂O₃, etc.), hafnium oxide (HfO₂, etc.), or a nitride of any of those metals. A film formed of a dielectric material can be exemplified such as barium titanate (BaTiO₃), strontium titanate (SrTiO₃), or calcium titanate (CaTiO₃). The insulating layer is preferably a resin-based insulating film (in particular, polyimide resin film).

The insulating layer may be formed by a printing method, or a vacuum evaporation method, a sputtering method, or the like may be used. Specifically, in a case of forming the resin-based insulating film, an insulating layer can be formed by applying a coating agent (which may be a resist containing a photosensitizer) in which a resin material is mixed in a medium to a formed position and thereafter drying the coating agent to subject it to heat treatment for hardening. In contrast, in a case of the inorganic insulator-based insulating layer, the insulating layer can be formed by a thin film formation method (sputtering method, etc.) using a mask. The insulating layer is preferably formed by a printing method (in particular, inkjet printing method) from a viewpoint of further reducing manufacturing cost and further improving manufacture easiness of TFT 3. In the present exemplary embodiment, a polyimide insulating layer is formed using a polyimide solution or a dispersion ink by the inkjet printing method. A thickness of the insulating layer is preferably within a range of about 0.1 μm to about 2 μm, and more preferably within a range of about 0.2 μm to about 1 μm (e.g., about 0.3 μm). The solvent is typically dried after the insulating layer is formed by a printing method. In this context, hardening may occur as needed. A drying temperature (hardening temperature) is typically 150° C. to 250° C., and preferably 150° C. to 220° C., and one example thereof is 180° C.

### Step of Forming Semiconductor Layer

The semiconductor layer is formed on the insulating layer. The semiconductor layer is preferably an organic semiconductor layer. A material of the organic semiconductor is preferably a high mobility material, and pentacene can be exemplified. Also, the material is not limited to pentacene, and examples of the organic semiconductor material that can be used for the present disclosure include nano-carbon materials (e.g., carbon nanotube, SiGe nanowire, fullerene, modified fullerene) and inorganic-organic composite materials (e.g., complex system of (C₆H₅C₂H₄NH₃) and SnI₄), besides high molecular materials (e.g., polythiophene or its derivative) and low molecular materials (e.g., pentacene or solubilized pentacene).

A method of forming the semiconductor layer is not specifically limited, and any method may be used as long as the semiconductor layer can be formed on the insulating layer. Specifically, in the manufacturing method of the present disclosure, the semiconductor layer is preferably formed by a printing method (in particular, inkjet printing method) from a viewpoint of further reducing manufacturing cost and further improving manufacture easiness of TFT 3. In the present exemplary embodiment, a printing method can be suitably used when, for example, a high molecular organic semiconductor layer (e.g., polythiophene such as poly-3-hexylthiophene (P3HT) or its derivative) is formed. To be more specific, the semiconductor layer can be formed by spraying a P3HT solution on an insulating film by an inkjet method and thereafter drying the P3HT solution, for example. Note that, in a case of a low molecule organic semiconductor (e.g., pentacene), an organic semiconductor layer may be formed by an evaporation process. A thickness of the semiconductor layer is preferably within a range of about 50 nm to about 150 nm, more preferably within a range of about 80 nm to about 120 nm, and about 100 nm for example. The solvent is typically dried after the semiconductor layer is formed by a printing method. A drying temperature is typically 150° C. to 250° C., and preferably 180° C. to 220° C., and one example thereof is 200° C.

### Step of Forming Source Electrode and Drain Electrode

The source electrode and the drain electrode are formed such that the semiconductor layer is disposed between the source electrode and the drain electrode in plan view. “Plan view” denotes a plane view when the source electrode and the drain electrode are viewed from above in a thickness direction of the TFT. Herein, “above” denotes “upper direction” when the TFT is formed on a surface of the circuit board as a substantially horizontal plane. Specifically, the source electrode and the drain electrode may be formed on the semiconductor layer so as to be separated from each other, or may be formed to be in contact with the semiconductor layer on the insulating layer. To be more specific, the source electrode and the drain electrode may be formed separated from each other on the semiconductor layer. As another method, the source electrode and the drain electrode may be formed separated from each other on the insulating layer such that the semiconductor layer is disposed between the source electrode and the drain electrode on the insulating layer and brought into contact with the electrodes.

As a material of the source electrode and the drain electrode, a metal having a good conductivity is preferable. For example, a metallic material such as silver (Ag), copper (Cu), nickel (Ni), aluminum (Al), or stainless steel (SUS) can be used. Formation of the source electrode and the drain electrode is not specifically limited, and a common practice electrode formation method may be employed. That is, the source electrode and the drain electrode may be formed by a printing method, or a vacuum evaporation method or a sputtering method may be used. The source electrode and the drain electrode are preferably formed by a printing method (in particular, inkjet printing method) from a viewpoint of further reducing manufacturing cost and further improving manufacture easiness of TFT 3. In the present exemplary embodiment, the source electrode and the drain electrode are formed by depositing a silver film with a silver nano-ink by an inkjet printing method. A thickness of each of the source electrode and the drain electrode is preferably within a range of about 0.02 μm to about 10 μm, and more preferably within a range of about 0.03 μm to about 1 μm (e.g., about 0.1 μm). An ink used for a printing method for forming the source electrode and the drain electrode is an ink including the above-mentioned metallic material (e.g., silver nano-ink). The ink for forming the source electrode and the drain electrode typically is an ink in which a metallic material is dispersed in a solvent. After the source electrode and the drain electrode are formed, the solvent is typically dried. A drying temperature is typically 100° C. to 200° C., and preferably 120° C. to 180° C., and one example thereof is 150° C.

### (Step T)

In step T, as illustrated in FIG. 2C and FIG. 3C, semiconductor chip 2 is mounted on underlayer 1. When no underlayer 1 is formed, semiconductor chip 2 is mounted on article S. A commercial item manufactured by NXP Semiconductors N.V., Impinj Inc., Alien Technology LLC, or the like can be used as the semiconductor chip (in particular, silicon chip). Any adhesive may be employed as long as it is conventionally used to combine to the substrate in a semiconductor chip field. FIG. 2C and FIG. 3C are respectively a schematic sketch and a schematic cross-sectional view illustrating a step of mounting the semiconductor chip in the manufacturing method of the semiconductor device of the present disclosure. Although underlayer 1 is formed in FIG. 2C and FIG. 3C, underlayer 1 need not necessarily be formed.

### (Step U)

In step U, as illustrated in FIG. 2D and FIG. 3D, antenna 4 and wiring 5 (not shown) are formed on underlayer 1 by a printing method. When no underlayer 1 is formed, antenna 4 and wiring 5 are formed on article S by a printing method. Although antenna 4 and wiring 5 are formed by a printing method, they need not necessarily be formed by the printing method, and may be formed by any thin film forming technology like for TFT 3. Examples of the thin film forming technology for forming antenna 4 and wiring 5 include the same thin film forming technology as the thin film forming technology exemplified in the description of the method of forming TFT 3, for example. It is preferable that antenna 4 and wiring 5 are manufactured by a printing method (in particular, inkjet printing method) from a viewpoint of further improving safety against peeling-off of the semiconductor device from the article, further reducing manufacturing cost, and further improving manufacture easiness. An ink used for the printing method for forming antenna 4 and wiring 5 is an ink including a conductive material such as silver (Ag), copper (Cu), nickel (Ni), aluminum (Al), or stainless steel (SUS) (e.g., silver nano-ink).

The ink for forming antenna 4 and wiring 5 is typically an ink in which a conductive material is dispersed in a solvent. After antenna 4 and wiring 5 are formed, the solvent is typically dried. A drying temperature is typically 100° C. to 200° C., and preferably 120° C. to 180° C., and one example thereof is 150° C. FIG. 2D and FIG. 3D are respectively a schematic sketch and a schematic cross-sectional view illustrating a step of forming the antenna and the wiring in the manufacturing method of the semiconductor device of the present disclosure. Although underlayer 1 is formed in FIG. 2D and FIG. 3D, underlayer 1 need not necessarily be formed.

### (Step V)

In step V, as illustrated in FIG. 2E and FIG. 3E, protection film 6 is formed on semiconductor chip 2, TFT 3 (not shown), antenna 4, wiring 5 (not shown) mounted or formed on underlayer 1 by a printing method. When no underlayer 1 is formed, protection film 6 is formed on semiconductor chip 2, TFT 3 (not shown), antenna 4, wiring 5 (not shown) mounted or formed on article S by a printing method. FIG. 2E and FIG. 3E are respectively a schematic sketch and a schematic cross-sectional view illustrating a step of forming the protection film in the manufacturing method of the semiconductor device of the present disclosure. Although underlayer 1 is formed in FIG. 2E and FIG. 3E, underlayer 1 need not necessarily be formed.

A method of forming protection film 6 is not specifically limited, and for example, can be formed by any coating method or printing method exemplified in the description for underlayer 1. The protection film is preferably manufactured by a printing method from a viewpoint of further improving safety against peeling-off of the semiconductor device from the article, further reducing manufacturing cost, and further improving manufacture easiness of the wiring. An ink used for a printing method for manufacturing the protection film is an ink including a polymer desired. The ink for forming the protection film may be an ink in which the polymer is dispersed in a solvent, or in which the polymer is dissolved in a solvent. After the protection film is formed, the solvent is typically dried. In this context, hardening may occur as needed. A drying temperature (hardening temperature) is typically 150° C. to 250° C., and preferably 150° C. to 220° C., and one example thereof is 180° C.

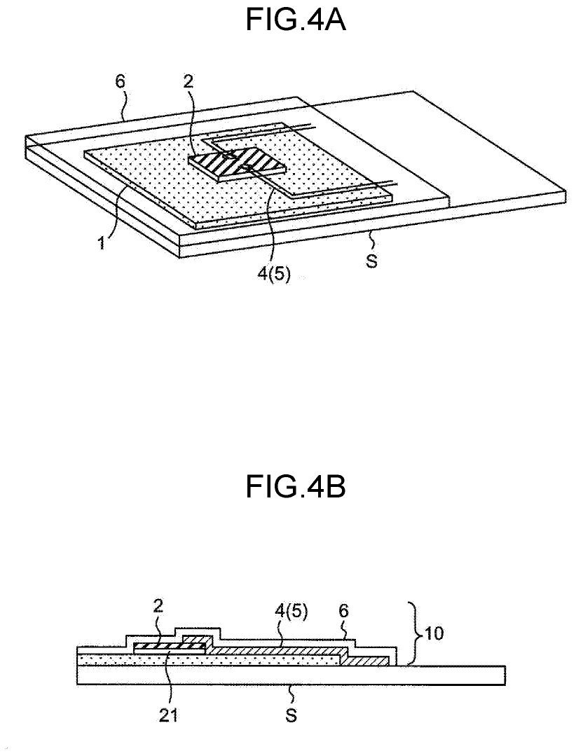

In semiconductor device 10 according to the present disclosure, when the surface of article S on which the semiconductor device 10 is fixed is made of a metal, article S (in particular, its metal surface) can be used as the antenna as illustrated in FIG. 4A and FIG. 4B. This makes the structure of the semiconductor device simple when the semiconductor device of the present disclosure is a wireless communication device. In FIG. 4A and FIG. 4B, antenna 4 also functions as wiring 5 for electrically connecting to the surface of article S. That is, the surface of article S is electrically connected to semiconductor device 10 (in particular, semiconductor chip 2). The semiconductor device illustrated in FIG. 4A and FIG. 4B is similar to the above-mentioned semiconductor device according to the present disclosure except that the surface or article S is electrically connected to semiconductor device 10 (in particular, semiconductor chip 2) by antenna 4 (or wiring 5). FIG. 4A and FIG. 4B are respectively a schematic sketch and a schematic cross-sectional view illustrating a still another example of the structure of the semiconductor device of the present disclosure.

Note that, it goes without saying that the step related to the semiconductor chip among the above-mentioned steps is not performed when semiconductor device 10 includes no semiconductor chip.

### INDUSTRIAL APPLICABILITY

The semiconductor device of the present disclosure is useful as a wireless communication device. The wireless communication device of the present disclosure includes a so called RFID tag, IC tag, and the like, and is extremely useful for distribution management (logistics management), production management, stock management, location management, history management, and the like in retail industry such as convenience stores and supermarkets, apparel industry, transportation industry, publishing industry (library), and the like.

### REFERENCE MARKS IN THE DRAWINGS

1 underlayer
2 semiconductor chip
21 adhesive layer
3 TFT
4 antenna
5 wiring
6 protection film
10 semiconductor device (e.g., wireless communication device)

1. A semiconductor device comprising:
a semiconductor chip; and
an antenna,
wherein the semiconductor chip and the antenna are directly fixed on a surface of an article and exposed from the surface of the article by more than or equal to ½ of respective height dimensions in respective thickness directions.

2. A semiconductor device comprising:
a thin film transistor; and
an antenna,
wherein the thin film transistor and the antenna are directly fixed on a surface of an article.

3. The semiconductor device according to claim 2, further comprising a semiconductor chip.

4. The semiconductor device according to claim 1, wherein the semiconductor chip is a silicon chip.

5. A semiconductor device comprising:
at least one of a semiconductor chip and a thin film transistor on an underlayer of the semiconductor device; and
an antenna on the underlayer,
wherein
the at least one of the semiconductor chip and the thin film transistor, and the antenna are directly fixed on a surface of the underlayer, and
the underlayer is directly fixed on a surface of an article.

6. The semiconductor device according to claim 2, wherein the thin film transistor is an organic thin film transistor.

7. The semiconductor device according to claim 1, wherein the semiconductor chip is a semiconductor bare chip.

8. The semiconductor device according to claim 1, wherein
the semiconductor chip is fixed in a face-up manner,
the semiconductor device further includes a wiring, and
the antenna and the wiring are printed components.

9. The semiconductor device according to claim 1, wherein
the semiconductor device is a wireless communication semiconductor device, and
the semiconductor device includes the antenna, the wiring, and at least one of the semiconductor chip and the thin film transistor.

10. The semiconductor device according to claim 9, wherein
a surface of the article on which the semiconductor device is fixed is made of a metal, and
the surface of the article is electrically connected to the semiconductor device to function as the antenna.

11. The semiconductor device according to claim 1, wherein the surface of the article on which the semiconductor device is fixed has a three-dimensional shape.

12. A manufacturing method of a semiconductor device including (i) a semiconductor chip and (ii) one or more components selected from a group including a thin film transistor, an antenna, and a wiring, the manufacturing method comprising at least one step among following steps P1 and Q1:
step P1 of directly mounting the semiconductor chip on a surface of an article; and
step Q1 of directly forming the one or more components selected from the group including the thin-film transistor, the antenna, and the wiring on the surface of the article by a printing method.

13. A manufacturing method of a semiconductor device including, on an underlayer, one or more components selected from a group including a semiconductor chip, a thin-film transistor, an antenna, and a wiring, the manufacturing method comprising following step O and at least one of following steps P2 and Q2:
step O of directly forming the underlayer on a surface of an article;
step P2 of directly mounting the semiconductor chip on a surface of the underlayer; and
step Q2 of directly forming the one or more components selected from a group including the thin-film transistor, the antenna, and the wiring on the surface of the underlayer by a printing method.

14. The manufacturing method of the semiconductor device according to claim 12, wherein the article is a marketable finished product.
